(19) United States
(12) Patent Application Publication
(10) Pub. No.: US 2017/0062352 A1
(43) Pub. Date: Mar. 2, 2017

(54) SEMICONDUCTOR CHIP MODULE

(71) Applicant: Avago Technologies General IP (Singapore) Pte. Ltd., Singapore (SG)

(72) Inventors: Deog-Soon Choi, Seoul (KR); Aaron Lee, Seoul (KR); Yong-Hyun Park, Seoul (KR); Nitesh Kumbhat, San Jose, CA (US)

(21) Appl. No.: 14/836,808

(22) Filed: Aug. 26, 2015

(51) Int. Cl. H01L 23/552; H01L 23/31; H01L 23/498; H01L 23/66

(52) U.S. Cl. CPC H01L 23/552; H01L 23/66; H01L 23/3114; H01L 23/49838

(57) ABSTRACT

A semiconductor chip module includes a substrate, a first radio frequency (RF) circuit block and a second RF circuit block mounted thereon, a conductive wall and a molding layer. The conductive wall is electrically connected to a ground potential and arranged between the first RF circuit block and the second RF circuit block. The molding layer is disposed over the substrate to cover the first RF circuit block and the second RF circuit block.

### BACKGROUND

In order to reduce the size of an electronic device, efforts have been made to similarly reduce the size of a semiconductor chip module used in the electronic device, in which active elements, e.g., a transistor and a semiconductor die, and passive elements, e.g., a resistor, a capacitor and an inductor are integrated. However, reduction in the size of a semiconductor chip module may cause electromagnetic interferences among the elements contained therein, and may adversely affect the performance of the elements.

What is needed, therefore, is a semiconductor chip module that is small in size but capable of preventing electromagnetic interferences among the elements contained therein.

### BRIEF DESCRIPTION OF THE DRAWINGS

The exemplary embodiments provided herein may be best understood when read with the accompanying drawings. It should be noted that various features depicted therein are not necessarily drawn to scale, for the sake of clarity and discussion. Wherever applicable and practical, like reference numerals refer to like elements.

FIG. 1 is a longitudinal sectional view of a semiconductor chip module in accordance with an embodiment.

FIGS. 2A to 2D show a process for manufacturing the semiconductor chip module shown in FIG. 1.

FIGS. 3A and 3B illustrate examples of a structure of a conductive wall in accordance with an embodiment.

FIG. 4 presents a sectional perspective view of the semiconductor chip module shown in FIG. 1.

FIGS. 5A to 5D depict modified examples of the semiconductor chip module shown in FIG. 1.

FIG. 6 offers a sectional perspective view of a semiconductor chip module in accordance with another embodiment.

FIG. 7 provides a first modified example of the semiconductor chip module shown in FIG. 6.

FIG. 8 represents a second modified example of the semiconductor chip module shown in FIG. 6.

### DETAILED DESCRIPTION

In the following detailed description, for purposes of explanation but not limitation, representative embodiments disclosing specific details are set forth in order to facilitate a better understanding of the present teachings. However, it will be apparent to one having ordinary skill in the art having had the benefit of the present disclosure that other embodiments in accordance with the present teachings that depart from the specific details disclosed herein may still remain within the scope of the appended claims. Moreover, descriptions of well-known apparatuses and methods may be omitted so as to not obscure the description of the representative embodiments.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms “a,” “an” and “the” include both singular and plural referents, unless the context clearly dictates otherwise. Thus, for example, “a device” may include a single or plural devices.

Although the terms “first,” “second,” etc. may be used herein to describe various elements, these elements should not be limited by these terms. These terms are used to distinguish one element from another. For example, a first element could be termed a second element, and, similarly, a second element could be termed a first element, without departing from the scope of the present teachings.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present Other words used to describe the relationship between elements should be interpreted in a like fashion (e.g., “between” versus “directly between,” “adjacent” versus “directly adjacent,” etc.). Similarly, an element that is disposed “on” another element generally means the element is directly on the other element; whereas an element that is “over” another element may be directly on the other element, or having one or more elements therebetween. Finally, relative terms, such as “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described an upper element, for example, would now be a “lower” element.

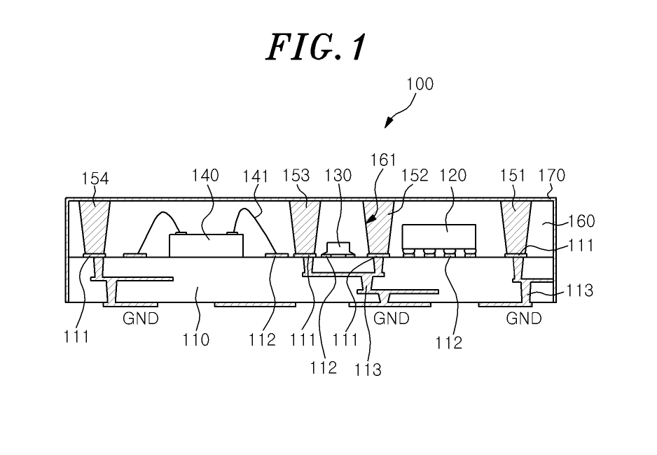

FIG. 1 is a longitudinal sectional view of a semiconductor chip module 100 in accordance with an embodiment.

Referring to FIG. 1, the semiconductor chip module 100 comprises a substrate 110, first and second semiconductor die 120 and 140, a passive element 130, conductive walls 151, 152, 153 and 154, a molding layer 160, and a conductive coating layer 170. The semiconductor chip module 100 shown in FIG. 1 is a multichip module including a plurality of semiconductor die 120 and 140. A package including a substrate and a single chip mounted over the substrate is called a single chip module. A package such as a multichip module or a single chip module may be referred to as a first level package. The first level package may be mounted on a printed circuit board (PCB) (not shown), and a package including the PCB and one or more first level packages mounted over the PCB may be referred to as a second level package. The second level package may be mounted on a mother board, and a package including the mother board and at least one second level package mounted over the mother board is called a third level package.

The substrate 110 comprises at least one ground pad 111 and signal pad 112 on an upper surface thereof. The substrate 110 also comprises a ground path 113 extending from the ground pad 111 through an inside of the substrate 110 to a lower surface of the substrate 100. An exposed portion of the ground path 113 at the lower surface of the substrate 110 may be grounded through the printed circuit board (PCB) (not shown) over which the semiconductor chip module 100 is mounted. The ground pad 111, the signal pad 112, and the ground path 113 may be made of an electrically conductive material such as copper.

The first and second semiconductor die 120 and 140 are mounted over the upper surface of the substrate 110 and electrically connected to the signal pad 112. A first semiconductor die 120 is electrically connected to the signal pad 112 by soldering. A second semiconductor die 140 is electrically connected to the signal pad 112 through a bonding wire 141.

The passive element 130 may be mounted over the upper surface of the substrate 110 and connected to the signal pad 112. The passive element 130 may be any one of a resistor, a capacitor and an inductor.

A radio frequency (RF) circuit block is a unit performing a predetermined process on an RF signal, and includes at least one circuit element (the semiconductor die, the passive element or the like) mounted over the substrate 110. FIG. 1 shows that the lint semiconductor die 120, the passive element 130 and the second semiconductor die 140 are separate RF circuit blocks.

The conductive walls 151, 152, 153 and 154 are made of an electrically conductive material such as copper and electrically connected to a ground potential GND through the ground pad 111 provided over the substrate 110. The conductive walls 151, 152, 153 and 154 are provided between the RF circuit blocks and/or to surround the RF circuit blocks to block electromagnetic interference (EMI) between the RF circuit blocks. For example, the conductive wall 152 may be disposed between the first semiconductor die 120 (i.e., the first RF circuit block) and the passive element 130 (i.e., the second RF circuit block) to block EMI between the first semiconductor die 120 and the passive element 130. Likewise, the conductive wall 153 may be provided between the passive element 130 and the second semiconductor die 140 to block EMI between the passive element 130 and the second semiconductor die 140. An RF circuit block (e.g., a semiconductor die) may be surrounded by a portion of the conductive coating layer 170 covering at least one side surface of the molding layer 160 and at least one conductive wall.

The molding layer 160 is disposed over the substrate 110 to cover the first semiconductor die 120, the passive element 130 and the second semiconductor die 140 (i.e., the RF circuit blocks). The molding layer 160 is an insulator such as an epoxy resin. The molding layer 160 has trenches 161, and the conductive walls 151, 152, 153 and 154 are disposed in the trenches 161.

The conductive coating layer 170 is disposed to cover an upper surface of the molding layer 160 and upper surfaces of the conductive walls 151, 152, 153 and 154. The conductive coating layer 170 is made of an electrically conductive material such as copper. The conductive coating layer 170 may be disposed to cover one or more side surfaces of the molding layer 160 and one or more side surfaces of the substrate 110. The conductive coating layer 170 may be electrically connected to the ground path 113 to be grounded. Accordingly, the conductive walls 151, 152, 153 and 154 may be connected to the ground potential GND through the conductive coating layer 170. The conductive coating layer 170 electrically connected to the ground potential GND may shield the circuit elements in the semiconductor chip module 100 from EMI from the outside of the semiconductor chip module 100.

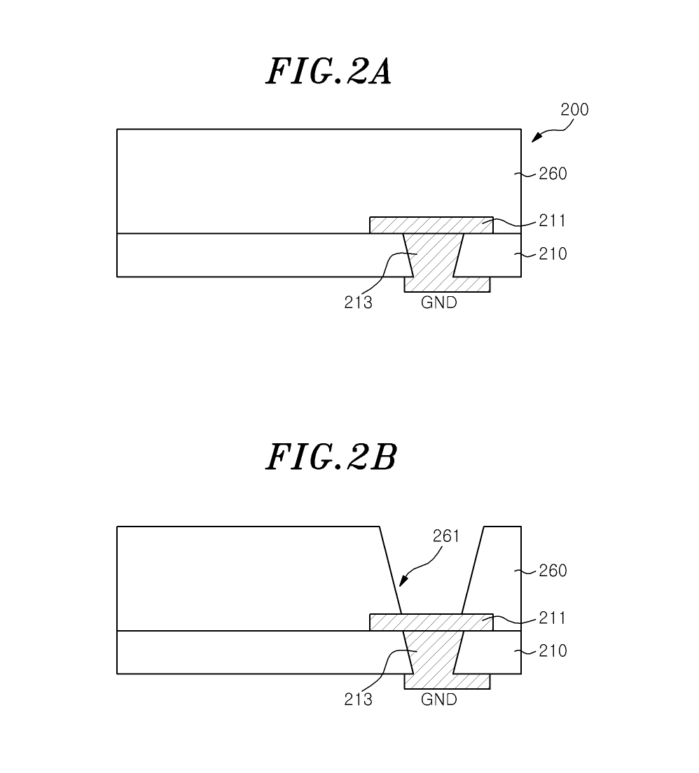

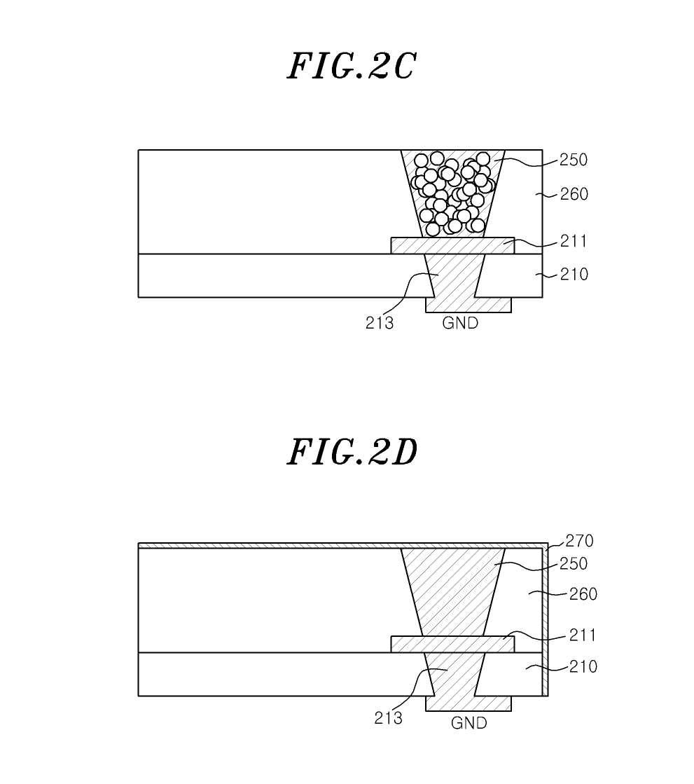

FIGS. 2A to 2D show a process for manufacturing a semiconductor chip module 200.

First, as shown in FIG. 2A, circuit elements (not shown) such as a semiconductor die and a passive element are mounted on a substrate 210, and then a molding layer 260 is disposed to cover an upper surface of the substrate 210. A ground pad 211 is provided over the upper surface of the substrate 210 and connected to a ground potential GND through a ground path 213 in the substrate 210.

Subsequently, as shown in FIG. 2B, a trench 261 is disposed in the molding layer 260. The ground pad 211 is exposed through the trench 261. The trench 261 may be disposed by using a laser. The trench 261 may be disposed by using various physical or chemical methods. The trench 261 may have a width of approximately 50 nm to approximately 200 nm and the trench shape can be tapered (V/Y) or straight (I). The trench 261 may have a depth of approximately 350 nm to approximately 600 nm and, in one embodiment 438 nm. Accordingly, sophisticated techniques and equipment are required in the processes of forming the trench 261 and filling the trench 261 with an electrically conductive material as will be described later.

Subsequently, as shown in FIG. 2C, the trench 261 is filled with an electrically conductive material (e.g., copper) to form a conductive wall 250. For example, the trench 261 may be filled with a copper paste and the copper paste may be then cured to form the conductive wall 250. For example, curing may include first curing at approximately 60° C. for approximately 30 minutes and second curing at approximately 160° C. for approximately 60 minutes. Filling with the copper paste and curing of the copper paste may be repeated several times. The trench 261 may be formed by using a dry plating treatment or a wet plating treatment.

Subsequently, as shown in FIG. 2D, a conductive coating layer 270 is formed to cover an upper surface of the molding layer 260 and an upper surface of the conductive wall 250. The conductive coating layer 270 may be disposed to cover a side surface of the molding layer 260 and a side surface of the substrate 210. The thickness of the conductive coating layer 270 may appropriately adjusted depending on various embodiments. The conductive coating layer 270 may be formed by dry plating such as physical vapor deposition (PVD) or chemical vapor deposition (CVD).

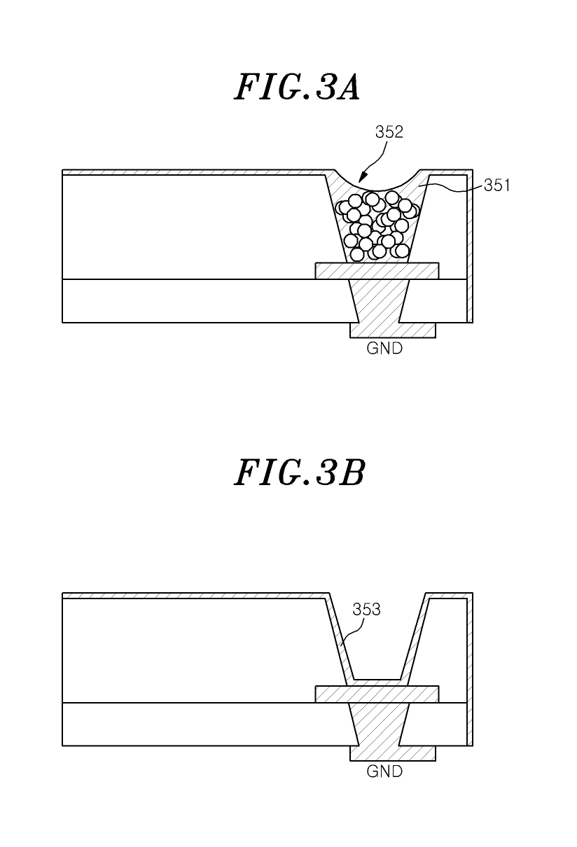

FIGS. 3A and 3B illustrate examples of a structure of a conductive wall in accordance with an embodiment.

As shown in FIG. 3A, a conductive wall 351 may have a recess portion 352 at an upper part thereof. Further, as shown in FIG. 3B, a conductive wall 353 may have a structure of a thin film covering a surface of a trench like the conductive coating layer. In connection therewith, the conductive wall may be integrated with the conductive coating layer, and both the conductive wall and the conductive coating layer may be formed at the same time.

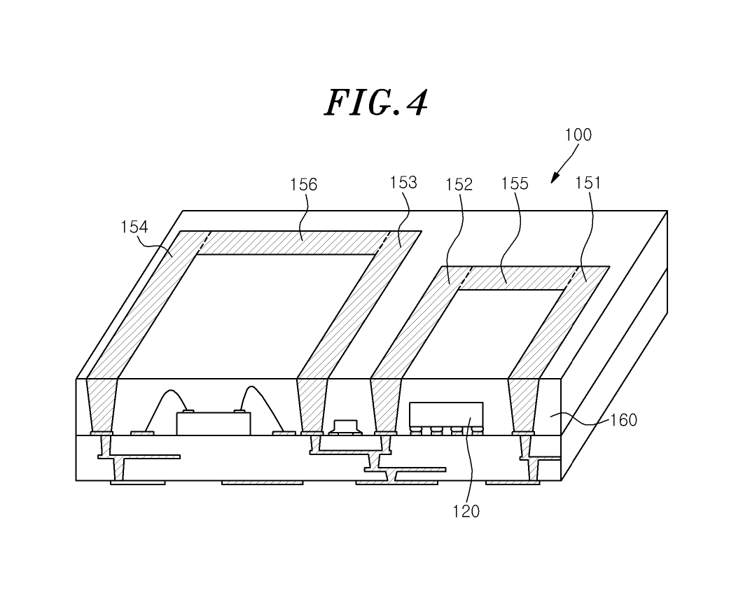

FIG. 4 is a sectional perspective view of the semiconductor chip module 100 shown in FIG. 1.

Referring to FIG. 4, the semiconductor chip module 100 may further include conductive walls 155 and 156. The conductive wall 151 and the conductive wall 152 extend in parallel to each other. One end of the conductive wall 155 is connected to one end of the conductive wall 151, and the other end of the conductive wall 155 is connected to one end of the conductive wall 152. Further, the semiconductor chip module 100 may further include a conductive wall (not shown) that extends in parallel to the conductive wall 155 and is connected to the other end of the conductive wall 151 at one end thereof and to the other end of the conductive wall 152 at the other end thereof. Accordingly, the first semiconductor die 120 surrounded by the conductive walls 151, 152 and 155 and the conductive wall (not shown) may be protected from EMI from other circuit elements (e.g., the passive element 130 and the second semiconductor die 140) in the semiconductor chip module 100.

Although not shown in FIG. 4, the semiconductor chip module 100 may further include a conductive coating layer disposed to cover the side surfaces and the upper surfaces of the molding layer 160, the upper surfaces of the conductive walls 151 to 156 and the side surfaces of the substrate 110.

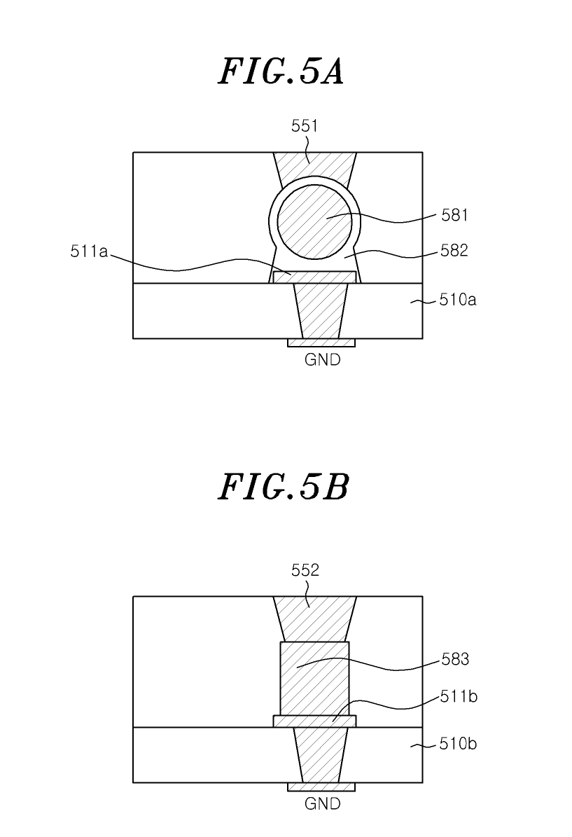

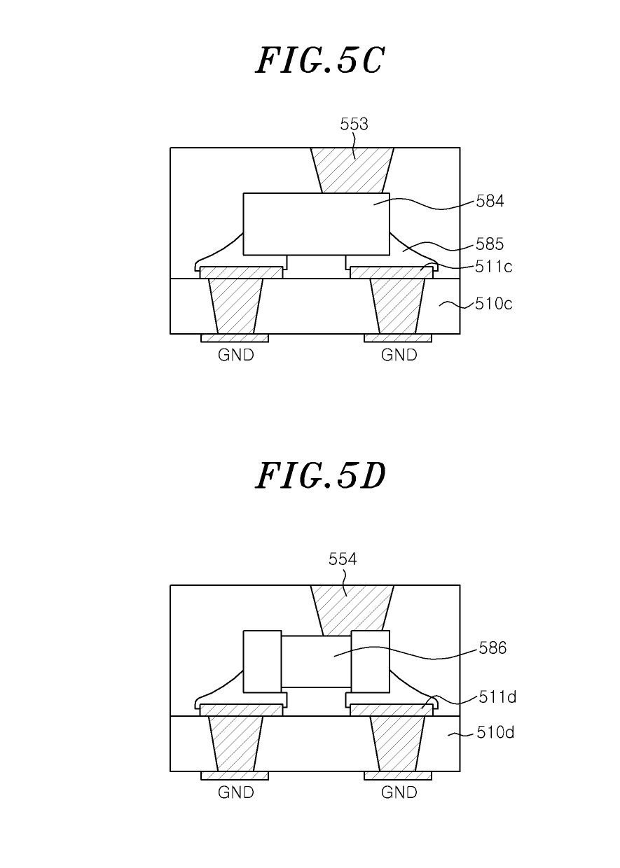

FIGS. 5A to 5D illustrate modified examples of the semiconductor chip module shown in FIG. 1.

Referring to FIG. 5A, a conductive bead 581 may be provided between an upper surface of a ground pad 511a provided on a substrate 510a and a lower surface of a conductive wall 551. The conductive bead 581 may be fixed to the upper surface of the ground pad 511a by soldering using a solder 582. The conductive wall 551 is electrically connected to the ground pad 511a through the conductive bead 581.

Referring to FIG. 5B, a copper post 583 may be provided between an upper surface of a ground pad 511b provided on a substrate 510b and a lower surface of a conductive wall 552. The copper post 583 may be formed by copper plating and integrated with the ground pad 511b. The conductive wall 552 is electrically connected to the ground pad 511b through the copper post 583.

Referring to FIG. 5C, a conductor 584 may be provided between an upper surface of a ground pad 511c provided on a substrate 510c and a lower surface of a conductive wall 553. The conductor 584 may be fixed to the upper surface of the ground pad 511c by soldering using solder 585. The conductive wall 553 is electrically connected to the ground pad 511c through the conductor 584.

Referring to FIG. 5D, a passive element 586 may be provided between an upper surface of a ground pad 511d provided on a substrate 510d and a lower surface of a conductive wall 554. The passive element 586 may be a resistor. The passive element 586 may be fixed to the upper surface of the ground pad 511d using soldering. The conductive wall 554 is electrically connected to the ground pad 511d through the passive element 586.

As shown in FIGS. 5A to 5D, when the conductive bead 581, the copper post 583, the conductor 584 or the passive element 586 is provided between the conductive wall and the ground pad, the depth of the trench required to dispose the conductive wall may be reduced as compared to the semiconductor chip module shown in FIG. 1, and thus, the size of the conductive wall may be reduced. Accordingly, workability of a process of forming the conductive wall may be improved.

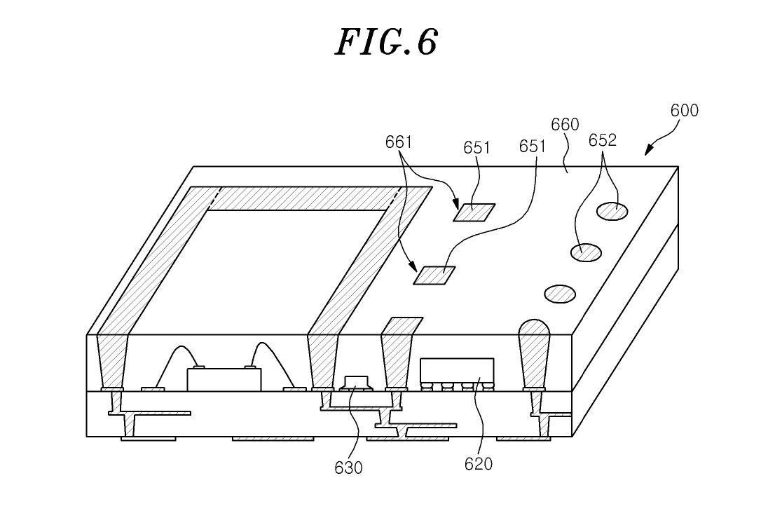

FIG. 6 is a sectional perspective view of a semiconductor chip module in accordance with another embodiment.

Referring to FIG. 6, the semiconductor chip module 600 may include a plurality of conductive poles 651 connected to the ground potential, instead of the conductive wall. The molding layer 660 has a plurality of through-holes 661 disposed at predetermined intervals, and a plurality of conductive poles 651 is formed through the through-holes 661. The conductive poles 651 are provided between a semiconductor die 620 and a passive element 630 to block EMI between the semiconductor die 620 and the passive element 630. Illustratively, the conductive poles 651 may have a rectangular cross section. Alternatively, conductive poles 651 having a circular cross section may be used. Depending on various embodiments, the shape of the cross section of the conductive pole may be variously modified. Further, the conductive poles may be disposed to surround the RF circuit block including at least one of the semiconductor die and the passive element.

When the conductive poles are used, an amount of copper used to block EMI may be reduced and workability of a process of forming the semiconductor chip module may be improved as compared to the use of the conductive wall.

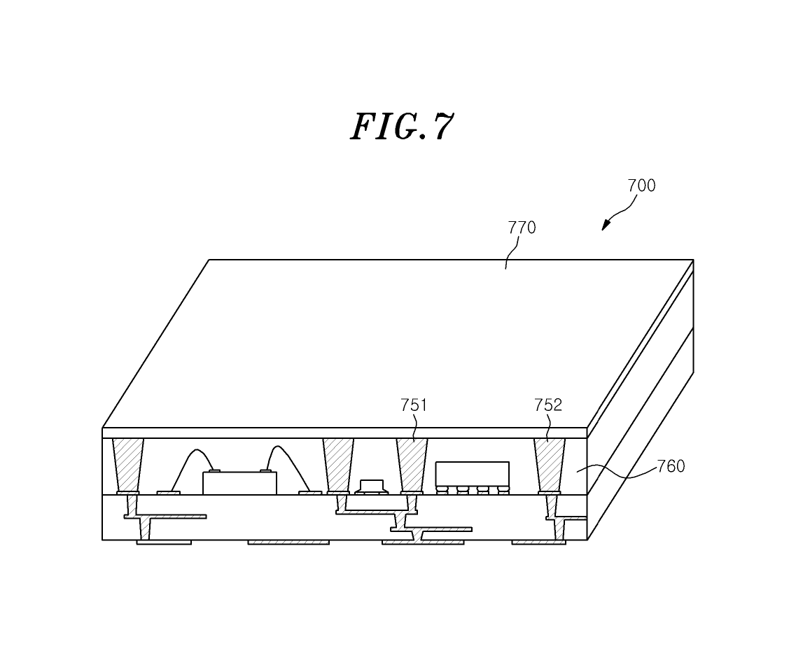

FIG. 7 illustrates a first modified example of the semiconductor chip module shown in FIG. 6.

Referring to FIG. 7, a semiconductor chip module 700 may further include a conductive coating layer 770 formed to cover an upper surface of a molding layer 760 and upper surfaces of conductive poles 751 and 752.

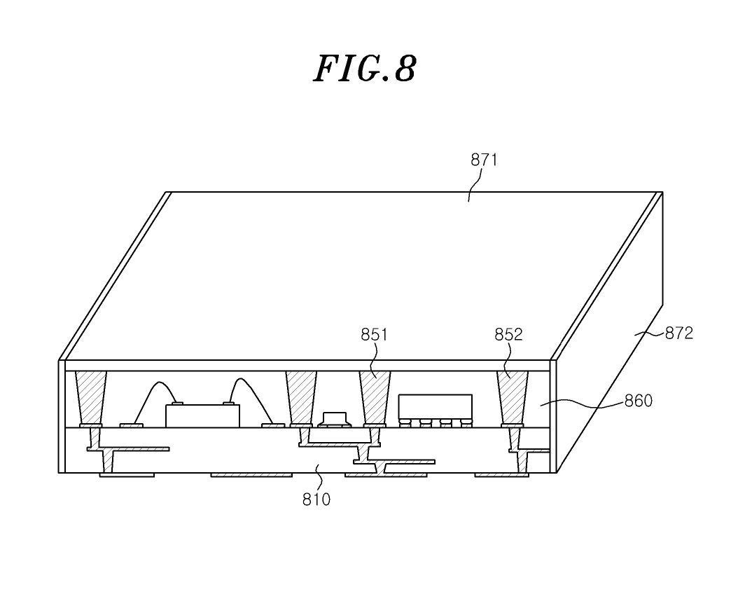

FIG. 8 illustrates a second modified example of the semiconductor chip module shown in FIG. 6.

Referring to FIG. 8, a semiconductor chip module 800 includes a conductive coating layer 871 formed to cover an upper surface of a molding layer 860 and upper surfaces of conductive poles 851 and 852, and also includes a conductive coating layer 872 formed to cover the side surfaces of a substrate 810 and the side surfaces of the molding layer 860. The conductive coating layer 871 and the conductive coating layer 872 may be integrated with each other or both may be formed.

In view of this disclosure, it is to be noted that the protection circuit can be implemented in a variety of elements and variant structures. Further, the various elements, structures and parameters are included for purposes of illustrative explanation only and not in any limiting sense. In view of this disclosure, those skilled in the art may be able to implement the present teachings in determining their own applications and needed elements and equipment to implement these applications, while remaining within the scope of the appended claims.

What is claimed is:

1. A semiconductor chip module comprising:
a substrate;
a first radio frequency (RF) circuit block mounted on the substrate;
a second RF circuit block mounted on the substrate;
a conductive wall electrically connected to a ground potential and arranged between the first RF circuit block and the second RF circuit block; and
a molding layer formed on the substrate to cover the first RF circuit block and the second RF circuit block.

2. The semiconductor chip module of claim 1, wherein the molding layer comprises a trench formed between the first RF circuit block and the second RF circuit block, and
wherein the conductive wall is formed in the trench.

3. The semiconductor chip module of claim 1, wherein the substrate comprises a ground pad on an upper surface thereof, and
wherein the conductive wall is electrically connected to the ground potential through the ground pad.

4. The semiconductor chip module of claim 3, further comprising a conductive bead provided between a lower surface of the conductive wall and an upper surface of the ground pad,
wherein the conductive wall is electrically connected to the ground pad through the conductive bead.

5. The semiconductor chip module of claim 3, further comprising a copper post formed on an upper surface of the ground pad,
wherein the conductive wall is electrically connected to the ground pad through the copper post.

6. The semiconductor chip module of claim 3, further comprising a conductor fixed to an upper surface of the ground pad,
wherein the conductive wall is electrically connected to the ground pad through the conductor.

7. The semiconductor chip module of claim 3, further comprising a passive element provided between a lower surface of the conductive wall and an upper surface of the ground pad,
wherein the conductive wall is electrically connected to the ground pad through the passive element.

8. The semiconductor chip module of claim 1, further comprising a conductive coating layer covering an upper surface of the molding layer and an upper surface of the conductive wall.

9. The semiconductor chip module of claim 8, wherein the conductive coating layer covers a side surface of the substrate and a side surface of the molding layer.

10. The semiconductor chip module of claim 8, wherein the conductive wall is electrically connected to the ground potential through the conductive coating layer.

11. The semiconductor chip module of claim 1, further comprising an additional conductive wall extending from the conductive wall,
wherein the conductive wall and the additional conductive wall are disposed to surround the first RF circuit block.

12. The semiconductor chip module of claim 1, wherein the first RF circuit block comprises a semiconductor die.

13. A semiconductor chip module comprising:
a substrate;
a first RF circuit block mounted on the substrate;
a second RF circuit block mounted on the substrate;
a plurality of conductive poles electrically connected to a ground potential and provided between the first RF circuit block and the second RF circuit block; and
a molding layer formed on the substrate to cover the first RF circuit block and the second RF circuit block.

14. The semiconductor chip module of claim 13, wherein the molding layer comprises a plurality of through-holes between the first RF circuit block and the second RF circuit block, and
wherein the conductive poles are formed in the through-holes.

15. The semiconductor chip module of claim 13, wherein the substrate comprises ground pads on an upper surface thereof, and
wherein the conductive poles are electrically connected to the ground potential through the ground pads.

16. The semiconductor chip module of claim 13, further comprising a conductive coating layer covering an upper surface of the molding layer and upper surfaces of the conductive poles.

17. The semiconductor chip module of claim 16, wherein the conductive coating layer covers a side surface of the substrate and a side surface of the molding layer.

18. The semiconductor chip module of claim 13, further comprising a plurality of additional conductive poles electrically connected to the ground potential,
wherein the conductive poles and the additional conductive poles are disposed to surround the first RF circuit block.

19. The semiconductor chip module of claim 13, wherein the first RF circuit block comprises a semiconductor die.

20. A semiconductor chip module comprising:
a substrate;
a first RF circuit block mounted on the substrate;
a second RF circuit block mounted on the substrate;
a molding layer disposed on the substrate to cover the first RF circuit block and the second RF circuit block, the molding layer comprising a trench disposed between the first RF circuit block and the second RF circuit block; and
a conductive coating layer electrically connected to a ground potential and covering a surface of the trench.
